(19) United States
(12) Patent Application Publication
(10) Pub. No.: US 2025/0316631 A1
(43) Pub. Date: Oct. 9, 2025

(54) ELECTRONIC DEVICE, DISPLAY DEVICE AND MANUFACTURING METHOD FOR THE SAME

(71) Applicant: SAMSUNG DISPLAY CO., LTD., YONGIN-SI (KR)

(72) Inventors: CHOLONG WON, Yongin-si (KR); KIYONG KIM, Yongin-si (KR); HEEJU WOO, Yongin-si (KR); HYUNGBIN CHO, Yongin-si (KR)

(21) Appl. No.: 19/063,530

(22) Filed: Feb. 26, 2025

(30) Foreign Application Priority Data
Apr. 9, 2024 (KR) 10-2024-0048325

(51) Int. Cl. H01L 23/00; H01L 25/16; H10K 59/127; H10K 59/82

(52) U.S. Cl. CPC H01L 24/13; H01L 24/05; H01L 24/16; H01L 24/32; H01L 24/73; H01L 25/167; H10K 59/1275; H10K 59/82; H01L 2224/0401; H01L 2224/05557; H01L 2224/13019; H01L 2224/16145; H01L 2224/32145; H01L 2224/73204

(57) ABSTRACT

A display device includes a display panel including a base substrate and a first pad disposed on the base substrate. A driving chip includes a chip pad corresponding to the first pad and a bump electrically connecting the first pad and the chip pad to each other. An adhesive member is disposed between the display panel and the driving chip. The adhesive member couples the first pad and the chip pad to each other. The bump includes a first surface and a second surface opposite to the first surface in a thickness direction of the base substrate. The bump includes a plurality of patterns on the first surface and the second surface.

### CROSS-REFERENCE TO RELATED APPLICATIONS

This application claims priority under 35 U.S.C. § 119 to Korean Patent Application No. 10-2024-0048325, filed on Apr. 9, 2024 in the Korean Intellectual Property Office, the disclosure of which is incorporated by reference in its entirety herein.

### 1. TECHNICAL FIELD

The present disclosure herein relates to a display device and a manufacturing method for the same, and more particularly, to a display device having increased coupling stability between a display panel and a driving chip and a manufacturing method for the same.

### 2. DISCUSSION OF RELATED ART

Various types of electronic devices include a display panel for displaying images to a user, such as televisions, mobile phones, tablet PCs, computers, navigation devices, and game consoles. The display panel includes a light-emitting element and a circuit for driving the light-emitting element. Light-emitting elements included in the display panel emit light according to a voltage applied from the circuit and generate an image from the emitted light. Research is being conducted on a connection of a light-emitting element and a circuit to increase the reliability of a display panel.

### SUMMARY

Embodiments of the present disclosure provides a display device having increased coupling reliability between a display panel and a driving chip.

Embodiments of the present disclosure also provides a manufacturing method for a display device having increased coupling reliability between a display panel and a driving chip.

According to an embodiment of the present inventive concept a display device includes a display panel including a base substrate and a first pad disposed on the base substrate. A driving chip includes a chip pad corresponding to the first pad and a bump electrically connecting the first pad and the chip pad to each other. An adhesive member is disposed between the display panel and the driving chip. The adhesive member couples the first pad and the chip pad to each other. The bump includes a first surface and a second surface opposite to the first surface in a thickness direction of the base substrate. The bump includes a plurality of patterns on the first surface and the second surface.

In an embodiment, the first pad may be in direct contact with the second surface of the bump.

In an embodiment, the display device may further include a plurality of insulating patterns disposed between the base substrate and the first pad, and the first pad may cover the plurality of insulating patterns.

In an embodiment, the plurality of insulating patterns may overlap the bump in a plan view.

In an embodiment, the driving chip may include a bump electrode partially covering the chip pad and a metal layer disposed on the chip pad and the bump electrode.

In an embodiment, the bump may be disposed between the metal layer and the first pad in the thickness direction of the base substrate.

In an embodiment, the plurality of patterns of the bump may include a plurality of first patterns recessed from the first surface in the thickness direction of the base substrate and a plurality of second patterns recessed from the second surface in the thickness direction of the base substrate.

In an embodiment, the plurality of first patterns may include a first recess recessed from the first surface, the plurality of second patterns may include a second recess recessed from the second surface, and the first recess of the plurality of first patterns and the second recess of the plurality of second patterns may be alternately arranged along one direction.

In an embodiment, the metal layer may include a plurality of metal patterns corresponding to the plurality of first patterns of the bump.

In an embodiment, the plurality of first patterns may overlap the plurality of metal patterns of the metal layer.

In an embodiment, the plurality of metal patterns of the metal layer may be in direct contact with the first surface of the bump and the first recess of the plurality of first patterns.

In an embodiment, the plurality of first patterns may include a first recess recessed from the first surface, the plurality of second patterns may include a second recess recessed from the second surface, and the first recess may not overlap the second recess in a plan view.

In an embodiment, the plurality of first patterns may be adjacent to the metal layer, and the plurality of second patterns may be adjacent to the first pad.

In an embodiment, the plurality of first patterns and the plurality of second patterns may each include a plurality of recesses.

According to an embodiment of the present inventive concept, a manufacturing method for a display device includes preparing a preliminary driving chip including a chip pad, a bump electrode partially covering the chip pad, and a preliminary metal layer disposed on the chip pad and the bump electrode. The preliminary metal layer is etched to form a metal layer. A bump is formed on the metal layer. The bump includes a plurality of first patterns and a plurality of second patterns. The plurality of first patterns is adjacent to the metal layer. The plurality of second patterns are spaced apart from the metal layer in a cross-sectional view.

In an embodiment, the manufacturing method may further includes forming a photoresist on the preliminary driving chip. The photoresist layer includes a photo pattern. The forming of the metal layer by etching the preliminary metal layer may include forming a plurality of metal patterns corresponding to the photo pattern.

In an embodiment, the manufacturing method may further include preparing a display panel including a base substrate, a plurality of insulating patterns disposed on the base substrate, and a first pad covering the plurality of insulating patterns, and electrically connecting the chip pad and the first pad to each other by the bump.

In an embodiment, the forming of the bump on the metal layer includes forming the plurality of first patterns corresponding to a shape of the plurality of metal patterns, and forming the plurality of second patterns corresponding to the plurality of first patterns.

According to an embodiment of the present inventive concept, a display device includes a base substrate, an insulating layer disposed on the base substrate, and a plurality of insulating patterns disposed on the insulating layer. The plurality of insulating patterns is spaced apart from each other. A first pad covering the plurality of insulating patterns. A driving chip includes a chip pad corresponding to the first pad and a bump electrically connecting the first pad and the chip pad to each other. An adhesive member is disposed between the first pad and the driving chip. The adhesive member couples the first pad and the chip pad to each other.

In an embodiment, the driving chip may further include a bump electrode partially covering the chip pad, and a metal layer disposed on the chip pad and the bump electrode, the bump may include a plurality of first patterns recessed from a first surface adjacent to the metal layer in a thickness direction of the base substrate and a plurality of second patterns recessed from a second surface adjacent to the first pad in the thickness direction of the base substrate, and the plurality of second patterns may correspond to the plurality of insulating patterns.

### BRIEF DESCRIPTION OF THE DRAWINGS

The accompanying drawings are included to provide a further understanding of embodiments of the present inventive concept, and are incorporated in and constitute a part of this specification. The drawings illustrate non-limiting embodiments of the present inventive concept and, together with the description, serve to explain principles of the present inventive concept. In the drawings:

FIG. 1 is a perspective view of a display device according to an embodiment of the present inventive concept;

FIG. 2 is an exploded perspective view of a display device according to an embodiment of the present inventive concept;

FIG. 3 is a cross-sectional view of a circuit board connected to a display device according to an embodiment of the present inventive concept;

FIG. 4 is a cross-sectional view of a display module according to an embodiment of the present inventive concept;

FIG. 5 is a plan view of a display panel according to an embodiment of the present inventive concept;

FIG. 6 is a cross-sectional view of a display panel according to an embodiment of the present inventive concept;

FIG. 7 is a cross-sectional view of an input sensor according to an embodiment of the present inventive concept;

FIG. 8 is an exploded perspective view of a portion of a display module according to an embodiment of the present inventive concept;

FIG. 9 is a cross-sectional view of a portion of a display module taken along line I-I′ of FIG. 8 according to an embodiment of the present inventive concept; and

FIGS. 10A to 10I are cross-sectional views partially illustrating a manufacturing method for a display device according to embodiments of the present inventive concept.

### DETAILED DESCRIPTION OF EMBODIMENTS

In this specification, it will be understood that when an element (or a region, a layer, a portion, or the like) is referred to as being “on”, “connected to” or “coupled to” another element, it may be directly disposed on, connected or coupled to the other element, or an intervening element may be disposed therebetween. When an element (or a region, a layer, a portion, or the like) is referred to as being “directly on”, “directly connected to” or “directly coupled to” another element, no intervening elements may be disposed therebetween.

Like reference numerals or symbols refer to like elements. Also, in the drawings, the thicknesses, ratios, and dimensions of the elements may be exaggerated for effective description of the technical contents. The term “and/or” includes all of one or more combinations which may be defined by related elements.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of embodiments of the present disclosure. The singular forms include the plural forms as well unless the context clearly indicates otherwise.

Also, terms such as “below”, “on lower side”, “above”, and “on upper side” may be used to describe the relationships of the elements illustrated in the drawings. These terms have relative concepts and are described on the basis of the directions indicated in the drawings.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which embodiments of the present disclosure belong. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the present inventive concept will be described with reference to the drawings.

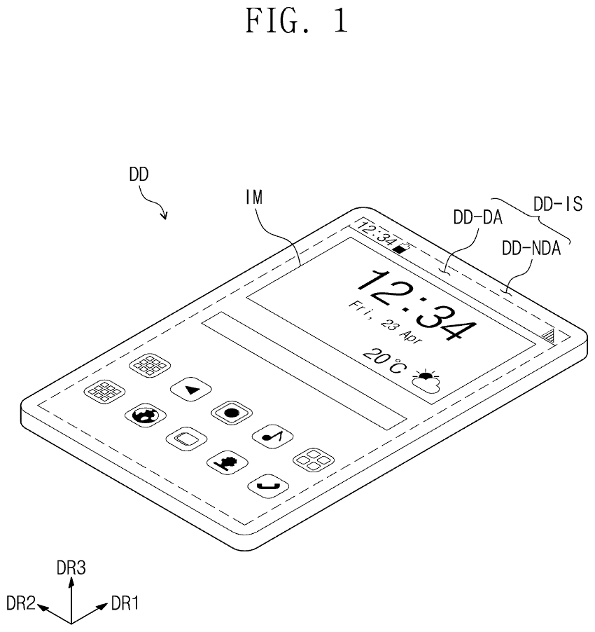

FIG. 1 is a perspective view of a display device according to an embodiment of the present inventive concept.

In an embodiment, a display device DD may be a large-sized electronic device such as a television, a monitor, or an outdoor billboard. In some embodiments, the display device DD may be a small-sized or medium-sized electronic device such as a personal computer, a laptop, a personal digital assistant, a car navigation unit, a game console, a smartphone, a tablet PC, and a camera. However, embodiments of the present inventive concept are not necessarily limited thereto and the display device DD may be employed as another type of a display device DD. FIG. 1 illustrates that the display device DD is a smartphone for convenience of explanation.

Referring to FIG. 1, the display device DD may display an image IM through a display surface DD-IS. Software application icons and a clock, temperature and calendar window are illustrated as an example of the image IM. However embodiments of the present inventive concepts are not necessarily limited thereto and the image IM may be various different subject matter comprising at least one moving and/or still image. In an embodiment, the display surface DD-IS may be parallel to a plane defined in a first direction DR1 and a second direction DR2. The display device DD may display the image IM from the display surface DD-IS in a normal direction of the display surface DD-IS. The normal direction of the display surface DD-IS may indicate a third direction DR3. In an embodiment, the first to third directions DR1 to DR3 may be perpendicular to each other. However, embodiments of the present disclosure are not necessarily limited thereto and the first to third directions DR1 to DR3 may cross each other at various different angles.

The display surface DD-IS may include a display region DD-DA in which the image IM is displayed and a non-display region DD-NDA adjacent to the display region DD-DA (e.g., in the first and/or second directions DR1, DR2). The non-display region DD-NDA may be a region in which the image IM is not displayed. However, embodiments of the present inventive concept are not necessarily limited thereto, and the non-display region DD-NDA may be adjacent to any one side of the display region DD-DA or omitted in some embodiments.

In this embodiment, a front surface (e.g., an upper surface) and a rear surface (e.g., a lower surface) of each member may be defined on the basis of a direction in which the image IM is displayed. A front surface and a rear surface may be opposed to each other in the third direction DR3, and a normal direction of each of a front surface and a rear surface may be parallel to the third direction DR3. However, directions indicated by first to third directions DR1, DR2, and DR3 may have relative concepts and may thus be changed into other directions. As used herein, the wording “in a plan view” may mean being viewed in the third direction DR3.

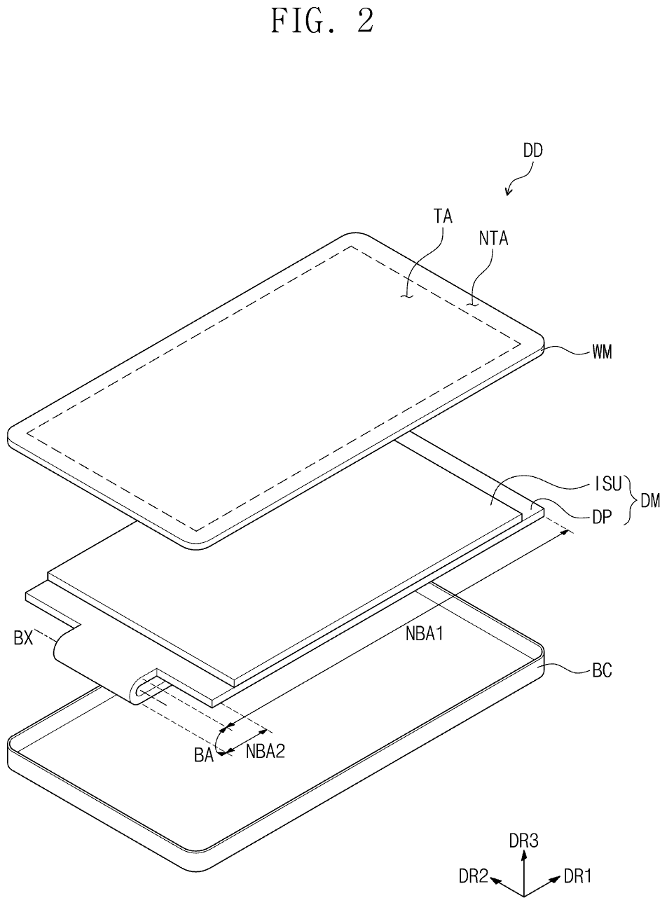

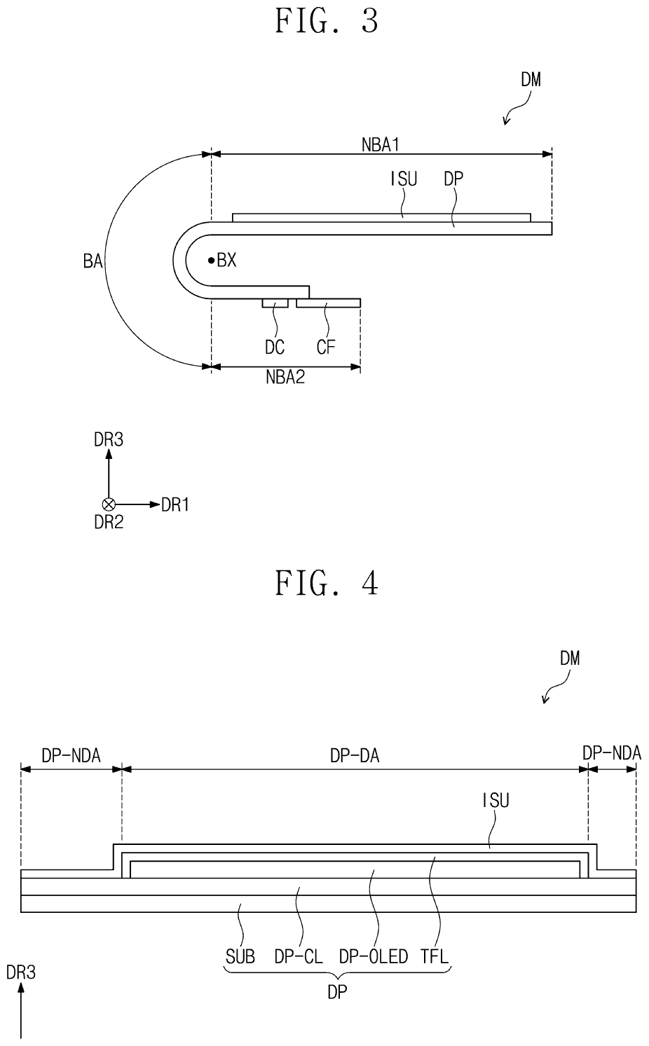

FIG. 2 is an exploded perspective view of the display device DD according to an embodiment of the present inventive concept. FIG. 3 is a cross-sectional view of a circuit board CF connected to the display device DD according to an embodiment of the present inventive concept.

Referring to FIG. 2, in an embodiment the display device DD may include a window WM, a display module DM, and an accommodation member BC (e.g., housing). In an embodiment, the display device DD may further include an optical member disposed between the window WM and the display module DM (e.g., in the third direction DR3). The optical member may include a polarizer.

The window WM may be disposed on the display module DM and transmit, to the outside (e.g., the external environment), an image (IM; FIG. 1) that is provided from the display module DM. In an embodiment, the window WM may include a transmission region TA and a non-transmission region NTA. The transmission region TA may overlap the display region DD-DA (see FIG. 1) and have a shape corresponding to that of the display region DD-DA. In an embodiment, the window WM may include a base layer and functional layers disposed on the base layer. In an embodiment, the functional layers may include a protective layer, an anti-fingerprint layer, and the like. The base layer of the window WM may be made of glass, sapphire, plastic, or the like. However, embodiments of the present inventive concept are not necessarily limited thereto.

The non-transmission region NTA may overlap the non-display region DD-NDA (see FIG. 1) and have a shape corresponding to that of the non-display region DD-NDA. The non-transmission region NTA may be a region having relatively low light transmittance compared to the transmission region TA. In an embodiment, the non-transmission region NTA may be defined by arranging a bezel pattern in a partial region of a base layer of the window WM, and a region in which the bezel pattern is not arranged may be defined as the transmission region TA. However, embodiments of the present disclosure are not necessarily limited thereto, and the non-transmission region NTA may be omitted.

The display module DM may be disposed under the window WM (e.g., in a direction opposite to the third direction DR3). The display module DM may be a component that substantially generates the image IM. The image IM generated from the display module DM may be displayed on the display surface DD-IS of the display module DM and viewed by a user from the outside (e.g., the external environment) through the transmission region TA. In an embodiment, the display module DM may include a display panel DP and an input sensor ISU.

According to an embodiment of the present inventive concept, the display panel DP may be any one among a liquid crystal display panel, an electrophoretic display panel, a microelectromechanical system (MEMS) display panel, an electrowetting display panel, an organic light-emitting display panel, an inorganic light-emitting display panel, and a quantum dot light-emitting display panel, but may not be particularly limited. Hereinafter, the display panel DP may be described as an organic light-emitting display panel for convenience of explanation.

In an embodiment, the input sensor ISU may include any one among a capacitive sensor, an optical sensor, an ultrasonic sensor, and an electromagnetic induction sensor. The input sensor ISU may be directly disposed on the display panel DP (e.g., in the third direction DR3). As used herein, the wording “a component A is directly disposed on a component B” means that no adhesive layer is disposed between a component A and a component B. In an embodiment, the input sensor ISU may be disposed on the display panel DP through a continuous process, or separately manufactured and then attached to an upper side of the display panel DP through an adhesive layer. However, embodiments of the present disclosure are not necessarily limited thereto.

Referring to FIGS. 2 and 3, the display module DM may further include a driving chip DC and the circuit board CF.

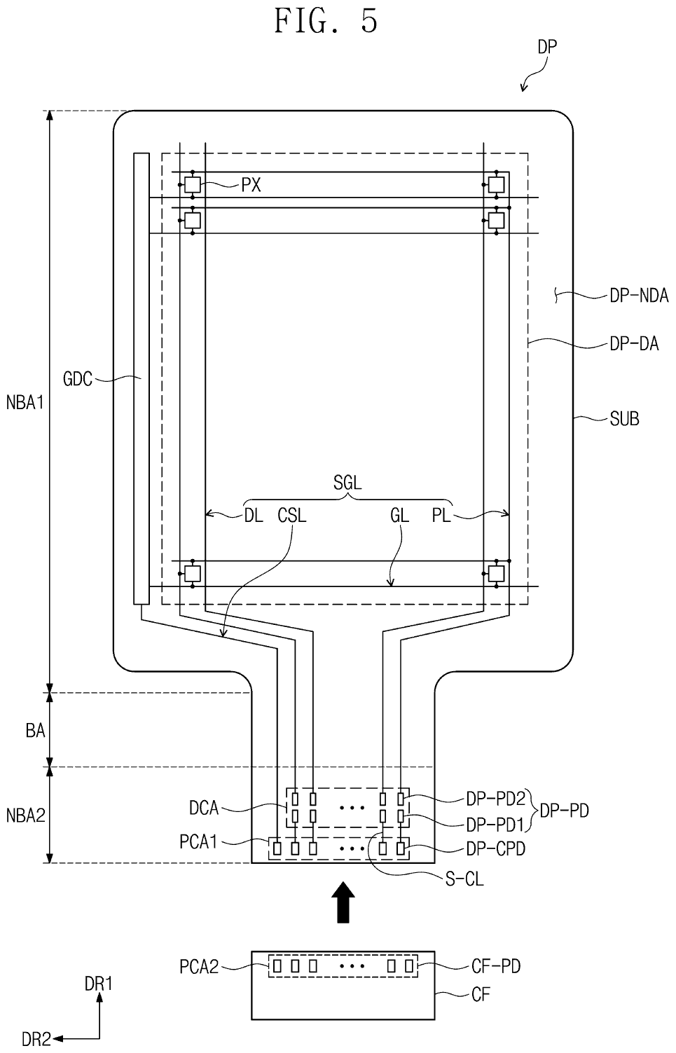

The driving chip DC and the circuit board CF may be coupled onto the display module DM. In an embodiment, a portion of the display panel DP on which the driving chip DC and the circuit board CF are disposed may be bent, and the driving chip DC and the circuit board CF may be disposed on (e.g., disposed directly thereon) a rear surface of the display panel DP. The driving chip DC may be mounted in a chip region DCA (see FIG. 5). An embodiment in which the driving chip DC is mounted on (e.g., mounted directly thereon) the display panel DP is illustrated. However, embodiments of the present inventive concept are not necessarily limited thereto. The driving chip DC may generate a driving signal which is required for an operation of the display panel DP on the basis of a control signal transferred from the circuit board CF. In an embodiment, the circuit board CF may be disposed on one end of a base substrate SUB (see FIG. 4) of the display panel DP and electrically connected to a circuit element layer DP-CL (see FIG. 4).

The accommodation member BC may be coupled to the window WM. The accommodation member BC may be coupled to the window WM and provide a predetermined inner space for receiving the display module DM, and the display module DM may be accommodated in the inner space. The accommodation member BC may stably protect components of the display device DD accommodated in the inner space from an external impact.

The display panel DP according to an embodiment may include a bending region BA, and a first non-bending region NBA1 and a second non-bending region NBA2 arranged to be spaced apart from each other in the first direction DR1 with the bending region BA therebetween when the display panel DP is in an unbent orientation. The bending region BA may be defined as a region in which the display panel DP is bent along a virtual bending axis BX extending in the second direction DR2. The first non-bending region NBA1 may be defined as a region overlapping the transmission region TA (e.g., in the third direction DR3), and the second non-bending region NBA2 may be defined as a region in direct contact with the circuit board CF.

When the bending region BA is bent with respect to the bending axis BX, the circuit board CF and the driving chip DC may be bent in a direction towards the rear surface of the display panel DP and be disposed on the rear surface of the display panel DP. In an embodiment, additional components may be disposed to compensate for a step, formed due to the bending region BA, between the circuit board CF and the rear surface of the display panel DP.

The display device DD is described above as a mobile phone terminal. However, the display device DD may include two or more electrically bonded electronic components. For example, the display panel DP and the driving chip DC mounted on the display panel DP may correspond to different electronic components, and the display device DD may be configured with just the display panel DP and the driving chip DC. However, embodiments of the present inventive concept are not necessarily limited thereto. In addition, the display device DD may be configured with just the display panel DP and the circuit board CF connected to the display panel DP. Hereinafter, the display device DD according to an embodiment of the present inventive concept will be described with a focus on a bonding structure of the display panel DP and the driving chip DC mounted on the display panel DP.

FIG. 4 is a cross-sectional view of the display module DM according to an embodiment of the present inventive concept. FIG. 4 will be described with reference to FIGS. 1 to 3, and repeated descriptions related to the same reference numerals or symbols may not be provided for economy of explanation.

Referring to FIG. 4, in an embodiment the display panel DP includes a base substrate SUB, a circuit element layer DP-CL disposed on the base substrate SUB (e.g., disposed directly thereon in the third direction D3), a display element layer DP-OLED, and an upper insulating layer TFL. The input sensor ISU may be disposed on (e.g., disposed directly thereon) the upper insulating layer TFL.

The display panel DP may include a display region DP-DA and a non-display region DP-NDA. The non-display region DP-NDA may surround the display region DP-DA (e.g., in the first and/or second directions DR1, DR2) The display region DP-DA of the display panel DP may correspond to the display region DD-DA illustrated in FIG. 1 or the transmission region TA illustrated in FIG. 2, and the non-display region DP-NDA may correspond to the non-display region DD-NDA illustrated in FIG. 1 or the non-transmission region NTA illustrated in FIG. 2.

In an embodiment, the base substrate SUB may include a synthetic resin film. The base substrate SUB may have a multi-layered structure. For example, in an embodiment the base substrate SUB may have a triple-layered structure of a synthetic resin layer, an inorganic layer, and a synthetic resin layer. For example, the synthetic resin layer may be a polyimide-based resin layer. However, embodiments of the present disclosure are not necessarily limited thereto, and a material of the synthetic resin layer may vary. In addition, the base substrate SUB may include a glass substrate, a metal substrate, an organic/inorganic composite material substrate, or the like.

The circuit element layer DP-CL may include at least one insulating layer and a circuit element. The insulating layer may include at least one inorganic layer and at least one organic layer. In an embodiment, the circuit element may include signal lines, a pixel driving circuit, and the like.

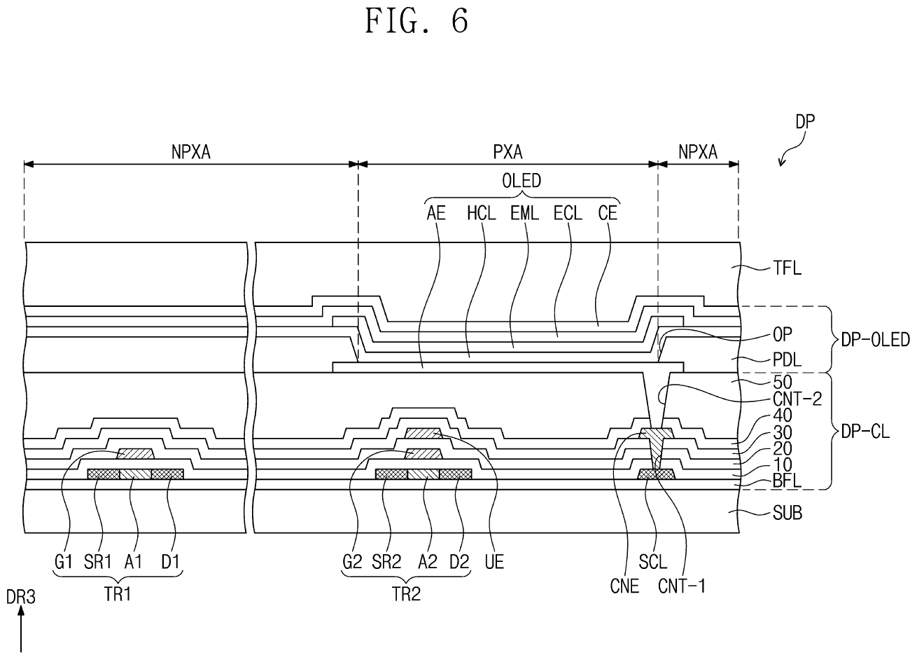

In an embodiment, the display element layer DP-OLED may include a plurality of organic light-emitting diodes. The display element layer DP-OLED may further include an organic layer such as a pixel-defining film PDL (see FIG. 6).

The upper insulating layer TFL may encapsulate the display element layer DP-OLED. For example, the upper insulating layer TFL may include a thin-film encapsulation layer. In an embodiment, the thin-film encapsulation layer may include a stacked structure of an inorganic layer/an organic layer/an inorganic layer. The upper insulating layer TFL may protect the display element layer DP-OLED from moisture, oxygen, and foreign substances such as dust particles. However, embodiments of the present inventive concept are not necessarily limited thereto, and the upper insulating layer TFL may further include an additional insulating layer in addition to the thin-film encapsulation layer. For example, in an embodiment the upper insulating layer TFL may further include an optical insulating layer for controlling refractive index.

In an embodiment of the present inventive concept, an encapsulation substrate may be provided instead of the upper insulating layer TFL. In this embodiment, the encapsulation substrate may be opposed to the base substrate SUB (e.g., in the third direction DR3) and coupled to the base substrate SUB with a separate adhesive member. The circuit element layer DP-CL and the display element layer DP-OLED may be disposed between the encapsulation substrate and the base substrate SUB (e.g., in the third direction DR3).

FIG. 5 is a plan view of the display panel DP according to an embodiment of the present inventive concept.

Referring to FIG. 5, the display panel DP may include a plurality of pixels PX, a gate driving circuit GDC, a plurality of signal lines SGL, first pads DP-PD, and second pads DP-CPD.

The pixels PX may be disposed in the display region DP-DA. In an embodiment, the pixels PX may each include an organic light-emitting diode and a pixel driving circuit connected thereto (e.g., electrically connected thereto). The gate driving circuit GDC and the signal lines SGL may be included in the circuit element layer DP-CL illustrated in FIG. 4.

The gate driving circuit GDC may sequentially output gate signals to a plurality of gate lines GL. In an embodiment, the gate driving circuit GDC may include a plurality of thin-film transistors which are formed through the same process as that for the driving circuit of the pixels PX, for example, a low temperature polycrystalline silicon (LTPS) process or a low temperature polycrystalline oxide (LTPO) process. The display panel DP may further include another driving circuit that provides an emission control signal to the pixels PX.

In an embodiment, the signal lines SGL may include the gate lines GL, data lines DL, a power line PL, and a control signal line CSL. The gate lines GL may each be connected to a corresponding pixel PX among the pixels PX, and the data lines DL may each be connected to a corresponding pixel PX among the pixels PX. The power line PL may be connected to the pixels PX. The control signal line CSL may provide control signals to a scan driving circuit. The signal lines SGL may overlap the display region DP-DA and the non-display region DP-NDA. In an embodiment, the signal lines SGL may each include a pad part and a line part. The pad part may be connected to an end of the line part, and the line part may overlap the display region DP-DA and the non-display region DP-NDA. The pad part may overlap a pad region to be described later.

In an embodiment, the display panel DP may include the first pads DP-PD and the second pads DP-CPD. The first pads DP-PD and the second pads DP-CPD may be disposed in the second non-bending region NBA2. Hereinafter, in this specification, among the non-display region DP-NDA, a region in which the first pads DP-PD are disposed may be defined as a chip region DCA, and a region in which the second pads DP-CPD are disposed may be defined as a first pad region PCA1.

The first pads DP-PD may be disposed in the chip region DCA. The driving chip DC (see FIG. 3) may be mounted in the chip region DCA. For example, the first pads DP-PD may be electrically connected to the driving chip DC and transfer an electrical signal received from the driving chip DC to the signal lines SGL. In an embodiment, the first pads DP-PD may include first row first pads DP-PD1 and second row first pads DP-PD2 arranged along the second direction DR2. The first row first pad DP-PD1 and the second row first pad DP-PD2 may be spaced apart from each other in the first direction DR1. However, a configuration and arrangement of the first pads DP-PD are not necessarily limited thereto, and the first pads DP-PD may be arranged in one row along the second direction DR2 or in three or more rows.

The second pads DP-CPD may be disposed in the first pad region PCA1. In an embodiment, the second pads DP-CPD may be arranged in the first pad region PCA1 along the second direction DR2. The first pads DP-PD and the second pads DP-CPD may be electrically connected to each other through bridge signal lines S-CL. The second pads DP-CPD may be spaced apart from the first pads DP-PD in the first direction DR1.

In an embodiment, the second pads DP-CPD may be arranged along the second direction DR2. However, a configuration and arrangement of the second pads DP-CPD are not necessarily limited thereto, and the second pads DP-CPD may include a plurality of row pads like the first pads DP-PD.

The circuit board CF may be rigid or flexible. For example, in an embodiment in which the circuit board CF is flexible, the circuit board CF may be provided as a flexible printed circuit board.

In an embodiment, the circuit board CF may include circuit pads CF-PD electrically connected to the display panel DP. The circuit pads CF-PD may be disposed in a second pad region PCA2 defined on the circuit board CF. In an embodiment, the circuit pads CF-PD may be arranged along the second direction DR2. For example, the circuit pads CF-PD may have an arrangement form in which the circuit pads CF-PD are in one-to-one correspondence with the second pads DP-CPD. For example, if the second pads DP-CPD are arranged along the second direction DR2, the circuit pads CF-PD may be arranged along the second direction DR2 so as to be in one-to-one correspondence with the second pads DP-CPD. However, a configuration and arrangement of the circuit pads CF-PD are not necessarily limited thereto.

The second pad region PCA2 of the circuit board CF may be disposed on the first pad region PCA1. For example, in an embodiment the second pad region PCA2 may be disposed to overlap the first pad region PCA1 (e.g., in the third direction DR3). The circuit pads CF-PD disposed in the second pad region PCA2 may be electrically connected to the second pads DP-CPD disposed in the first pad region PCA1 and transfer an electrical signal received from the circuit board CF to the second pads DP-CPD.

In an embodiment, the circuit board CF may include a timing control circuit for controlling an operation of the display panel DP. For example, in an embodiment the timing control circuit may be mounted on the circuit board CF in a form of an integrated chip. In addition, the circuit board CF may include an input sensing circuit for controlling the input sensor ISU.

In an embodiment, the display panel DP may include the first pads DP-PD to mount the driving chip DC. However, embodiments of the present inventive concept are not necessarily limited thereto. For example, in an embodiment the driving chip DC may be mounted on (e.g., mounted directly thereon) the circuit board CF, and in this embodiment, the first pads DP-PD of the display panel DP may be omitted.

According to an embodiment, a width of the first non-bending region NBA1 in the second direction DR2 may be greater than widths of the bending region BA and the second non-bending region NBA2 in the second direction DR2. However, embodiments of the present inventive concept are not necessarily limited thereto. In an embodiment, the bending region BA may have such a shape that a width of the bending region BA in the second direction DR2 decreases from the first non-bending region NBA1 towards the second non-bending region NBA2. However, embodiments of the present inventive concept are not necessarily limited thereto.

FIG. 6 is a cross-sectional view of the display panel DP according to an embodiment of the present inventive concept. FIG. 6 will be described with reference to FIG. 4, and repeated descriptions related to the same reference numerals or symbols may not be provided for economy of explanation.

Referring to FIG. 6, the display region DP-DA may include a light-emitting region PXA and a non-light-emitting region NPXA. In an embodiment, the pixels PX may each include an organic light-emitting diode OLED and a pixel driving circuit connected thereto. For example, in an embodiment the pixel PX may include a first transistor TR1, a second transistor TR2, and the organic light-emitting diode OLED. Some of the first and second transistors TR1 and TR2 of the pixel driving circuit may be illustrated.

The display panel DP may include a plurality of insulating layers, a semiconductor pattern, a conductive pattern, a signal line, etc. In an embodiment, an insulating layer, a semiconductor layer, and a conductive layer may be formed through coating, deposition, etc. The insulating layer, the semiconductor layer, and the conductive layer may then be selectively patterned through photolithography. Based on these processes, a semiconductor pattern, a conductive pattern, a signal line, etc. included in the display element layer DP-OLED and the circuit element layer DP-CL may be formed.

At least one inorganic layer may be formed on an upper surface of the base substrate SUB (e.g., disposed directly thereon in the third direction DR3). In an embodiment, the inorganic layer may include multiple layers. The multi-layered inorganic layers may constitute a buffer layer BFL.

A semiconductor pattern may be disposed on the buffer layer BFL (e.g., disposed directly thereon in the third direction DR3). In an embodiment, the semiconductor pattern may include polysilicon. However, embodiments of the present inventive concept are not necessarily limited thereto, and the semiconductor pattern may include amorphous silicon or metal oxide.

FIG. 6 illustrates a portion of a semiconductor pattern, but a semiconductor pattern may be further disposed in another region of the pixel PX in a plan view. For example, in an embodiment the semiconductor pattern may be arranged according to a specific rule across the pixels. The semiconductor pattern may have a different electrical property according to whether the semiconductor pattern is doped or not. The semiconductor pattern may include a first region and a second region. The first region may be doped with an N-type dopant or a P-type dopant. A P-type transistor may include a doped region doped with a P-type dopant.

The first region may have greater conductivity than the second region and substantially serve as an electrode or a signal line. The second region may have a low doping concentration or may be a non-doped region, and substantially correspond to an active A1 or A2 or a channel of the transistor TR1 or TR2. For example, a portion of a semiconductor pattern may be the active A1 or A2 of the transistor TR1 or TR2, another portion may be a source SR1 or SR2 or a drain D1 or D2 of the transistor TR1 or TR2, and still another portion may be a connection electrode CNE or a connection signal line SCL.

The source SR1, the active A1, and the drain D1 of the first transistor TR1 may be formed from a semiconductor pattern, and the source SR2, the active A2, and the drain D2 of the second transistor TR2 may be formed from a semiconductor pattern.

FIG. 6 illustrates a portion of the connection signal line SCL which is formed from a semiconductor pattern. However, the connection signal line SCL may be electrically connected to the drain D2 of the second transistor TR2 in a plan view. However, embodiments of the present disclosure are not necessarily limited thereto, and another transistor may be disposed between the connection signal line SCL and the drain D2 of the second transistor TR2 in some embodiments.

A first insulating layer 10 may be disposed on the buffer layer BFL (e.g., disposed directly thereon in the third direction DR3). The first insulating layer 10 may overlap the plurality of pixels PX in common and cover a semiconductor pattern. Gates G1 and G2 may be disposed on the first insulating layer 10 (e.g., disposed directly thereon in the third direction DR3). The gates G1 and G2 may overlap the actives A1 and A2 (e.g., in the third direction DR3). In an embodiment, in a process of doping the semiconductor pattern, the gates G1 and G2 may be used as a mask.

A second insulating layer 20 may be disposed on the first insulating layer 10 (e.g., disposed directly thereon in the third direction DR3) and cover the gates G1 and G2. In an embodiment, the second insulating layer 20 may overlap the pixels PX in common (e.g., in the third direction DR3). An upper electrode UE may be disposed on the second insulating layer 20 (e.g., disposed directly thereon in the third direction DR3). The upper electrode UE may overlap the gate G2 of the second transistor TR2 (e.g., in the third direction DR3). A portion of the gate G2 and the upper electrode UE overlapping the portion of the gate G2 may define a capacitor.

A third insulating layer 30 may be disposed on the second insulating layer 20 (e.g., disposed directly thereon in the third direction DR3) and cover the upper electrode UE. The connection electrode CNE may be disposed on the third insulating layer 30 (e.g., disposed directly thereon in the third direction DR3). In an embodiment, the connection electrode CNE may be connected to the connection signal line SCL through a contact hole CNT-1 passing through the first to third insulating layers 10, 20, and 30.

A fourth insulating layer 40 may be disposed on the third insulating layer 30 (e.g., disposed directly thereon in the third direction DR3) and cover the connection electrode CNE. The first to fourth insulating layers 10, 20, 30, and 40 may be an inorganic layer and/or an organic layer and may have a single- or multi-layered structure.

A fifth insulating layer 50 may be disposed on the fourth insulating layer 40 (e.g., disposed directly thereon in the third direction DR3). The fifth insulating layer 50 may be an organic layer. A first electrode AE may be disposed on the fifth insulating layer 50 (e.g., disposed directly thereon in the third direction DR3). In an embodiment, the first electrode AE may be connected to the connection electrode CNE through a contact hole CNT-2 passing through the fifth insulating layer 50 and the fourth insulating layer 40. For example, the first electrode AE may be connected to (e.g., electrically connected thereto) the connection signal line SCL through the contact holes CNT-1 and CNT-2.

A pixel-defining film PDL may be disposed on the fifth insulating layer 50 (e.g., disposed directly thereon in the third direction DR3). An opening OP may be defined in the pixel-defining film PDL. The opening OP of the pixel-defining film PDL may expose at least a portion of the first electrode AE. For example, in an embodiment the opening OP of the pixel-defining film PDL may expose a central portion of the first electrode AE. In this embodiment, the light-emitting region PXA may be defined to correspond to a partial region of the first electrode AE exposed by the opening OP.

A hole control layer HCL may be disposed on (e.g., disposed directly thereon) the first electrode AE and the pixel-defining film PDL. In an embodiment, the hole control layer HCL may be disposed in common in the light-emitting region PXA and the non-light-emitting region NPXA. In an embodiment, the hole control layer HCL may include a hole transport layer and further include a hole injection layer.

An emission layer EML may be disposed on the hole control layer HCL (e.g., disposed directly thereon in the third direction DR3). The emission layer EML may be disposed in a region corresponding to the opening OP. For example, the emission layer EML may be formed separately in each of the pixels.

An electron control layer ECL may be disposed on the emission layer EML (e.g., disposed directly thereon in the third direction DR3). The electron control layer ECL may include an electron transport layer and further include an electron injection layer. In an embodiment, the hole control layer HCL and the electron control layer ECL may be formed in common in the plurality of pixels using an open mask.

A second electrode CE may be disposed on (e.g., disposed directly thereon in the third direction DR3) the electron control layer ECL. In an embodiment, the second electrode CE may have an integrated shape and may be disposed in common in the plurality of pixels PX.

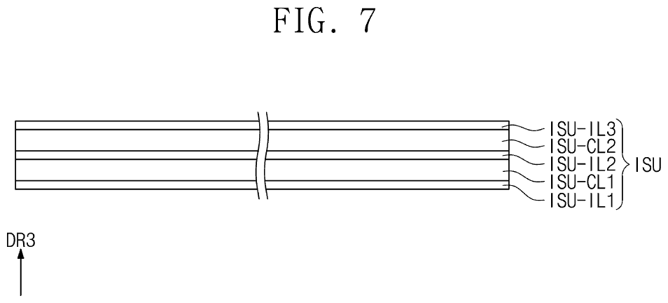

FIG. 7 is a cross-sectional view of the input sensor ISU according to an embodiment of the present inventive concept. FIG. 7 will be described with reference to FIG. 4, and repeated descriptions related to the same reference numerals or symbols may not be provided for economy of explanation.

Referring to FIG. 7, in an embodiment the input sensor ISU may include a first sensing insulating layer ISU-IL1, a first conductive layer ISU-CL1, a second sensing insulating layer ISU-IL2, a second conductive layer ISU-CL2, and a third sensing insulating layer ISU-IL3. The first sensing insulating layer ISU-IL1 may be directly disposed on (e.g., in the third direction DR3) the upper insulating layer TFL (see FIG. 4). However, embodiments of the present inventive concept are not necessarily limited thereto. For example, the first sensing insulating layer ISU-IL1 may be omitted in some embodiments.

The first conductive layer ISU-CL1 and the second conductive layer ISU-CL2 may each have a single-layered structure or a multi-layered structure in which layers are stacked along the third direction DR3. The conductive layer having a multi-layered structure may include at least one among transparent conductive layers and metal layers. In an embodiment, the transparent conductive layer may include indium tin oxide (ITO), indium zinc oxide (IZO), zinc oxide (ZnO), indium tin zinc oxide (ITZO), PEDOT, a metal nanowire, or graphene, and the metal layer may include molybdenum, silver, titanium, copper, aluminum, and an alloy thereof. However, embodiments of the present inventive concept are not necessarily limited thereto.

The conductive layer having a multi-layered structure may include metal layers including different metal. For example, in an embodiment at least any one of the first conductive layer ISU-CL1 or the second conductive layer ISU-CL2 may have a triple-layered metal layer structure, for example, a triple-layered structure of titanium/aluminum/titanium. Metal having relatively high durability and low reflectance may be applied to an outer layer, and metal having high electrical conductivity may be applied to an inner layer.

In an embodiment, the first conductive layer ISU-CL1 and the second conductive layer ISU-CL2 may each include a plurality of conductive patterns. For example, the first conductive layer ISU-CL1 may include first conductive patterns, and the second conductive layer ISU-CL2 may include second conductive patterns. The first conductive patterns and the second conductive patterns may each include sensing electrodes and signal lines connected thereto. The sensing electrodes of the first conductive patterns and the sensing electrodes of the second conductive patterns may be insulated from and cross each other.

The first to third sensing insulating layers ISU-IL1, ISU-IL2, and ISU-IL3 may each include an inorganic layer or an organic layer. In this embodiment, the first sensing insulating layer ISU-IL1 and the second sensing insulating layer ISU-IL2 may include an inorganic layer, and the third sensing insulating layer ISU-IL3 may include an organic layer. However, embodiments of the present inventive concept are not necessarily limited thereto, and any one of the first to third sensing insulating layers ISU-IL1, ISU-IL2, and ISU-IL3 of the input sensor ISU may be omitted.

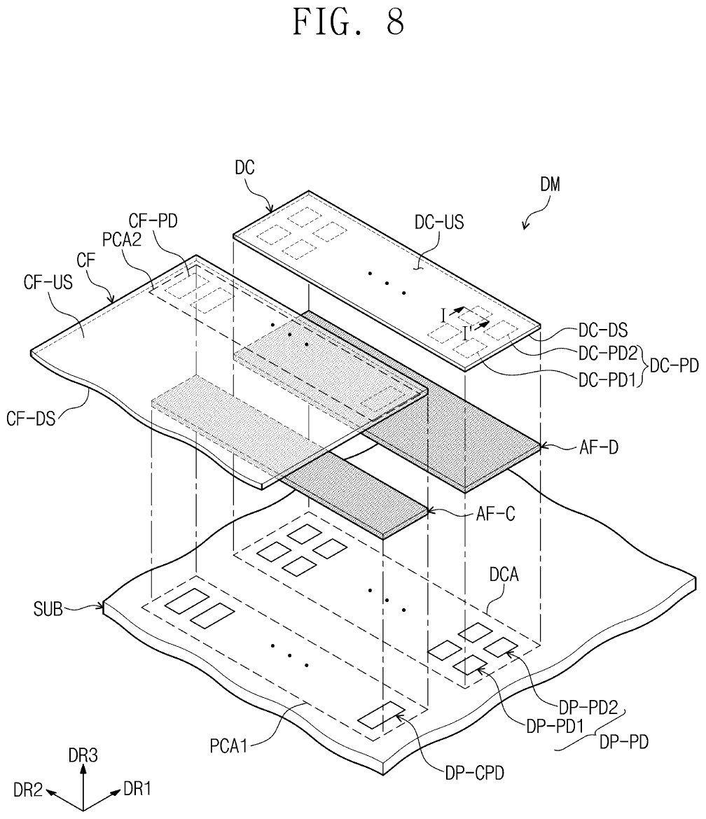

FIG. 8 is an exploded perspective view of a portion of the display module DM according to an embodiment of the present inventive concept. FIG. 8 will be described with reference to FIG. 5, and repeated descriptions related to the same reference numerals or symbols may not be provided for economy of explanation.

Referring to FIG. 8, the display module DM may further include a driving chip adhesive member AF-D and a circuit board adhesive member AF-C. The driving chip adhesive member AF-D may be disposed between the driving chip DC and the base substrate SUB (e.g., in the third direction DR3) and couple the driving chip DC and the base substrate SUB to each other, and the circuit board adhesive member AF-C may be disposed between the circuit board CF and the base substrate SUB (e.g., in the third direction DR3) and couple the circuit board CF and the base substrate SUB to each other. In an embodiment, the driving chip adhesive member AF-D and the circuit board adhesive member AF-C may be a non-conductive film (NCF). In the present specification, the driving chip adhesive member AF-D may be referred to as an adhesive member AF-D.

The circuit board CF may include an upper surface CF-US and a lower surface CF-DS. The lower surface CF-DS of the circuit board CF may be a surface facing the display panel DP (e.g., in a direction opposite to the third direction DR3). The circuit pads CF-PD may be disposed on (e.g., disposed directly thereon) the lower surface CF-DS of the circuit board CF and respectively electrically connected to the second pads DP-CPD of the display panel DP. The circuit pads CF-PD and the second pads DP-CPD may be respectively electrically connected through the circuit board adhesive member AF-C.

The driving chip DC may include an upper surface DC-US and a lower surface DC-DS. The lower surface DC-DS of the driving chip DC may be a surface facing the display panel DP (e.g., in a direction opposite to the third direction DR3). The driving chip DC may include chip pads DC-PD respectively electrically connected to the first pads DP-PD disposed on the base substrate SUB.

In an embodiment, the chip pads DC-PD may include first row chip pads DC-PD1 arranged along the second direction DR2 and second row chip pads DC-PD2 arranged along the second direction DR2. The first row chip pads DC-PD1 and the second row chip pads DC-PD2 may have a shape exposed to the outside from the lower surface of the driving chip DC. FIG. 8 illustrates that the chip pads DC-PD are arranged in two rows. However, embodiments of the present inventive concept are not necessarily limited thereto and the chip pads DC-PD may be arranged in a single row or three or more rows corresponding to an arrangement structure of the first pads DP-PD. The chip pads DC-PD and the first pads DP-PD may be respectively electrically connected to each other through the adhesive member AF-D.

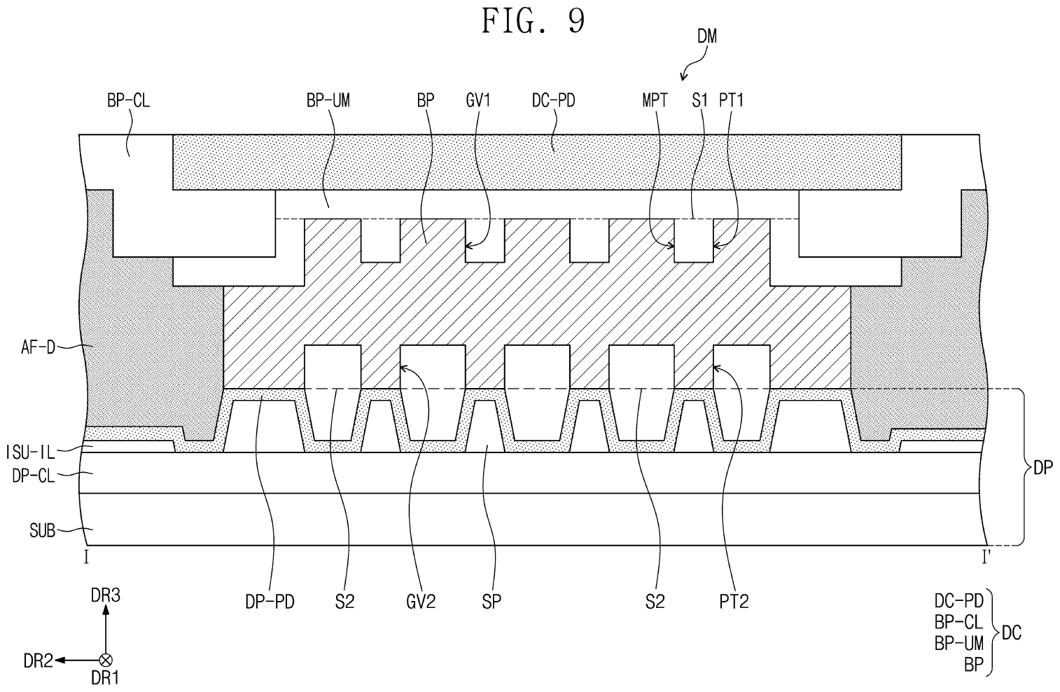

FIG. 9 is a cross-sectional view of a portion of the display module DM (see FIG. 2) taken along line I-I′ of FIG. 8. FIG. 9 will be described with reference to FIGS. 2 to 8, and repeated descriptions related to the same reference numerals or symbols may not be provided for economy of explanation. FIG. 9 illustrates a state in which the chip pad DC-PD and the first pad DP-PD are coupled to each other.

Referring to FIG. 9, in an embodiment the display panel DP may include the base substrate SUB, the circuit element layer DP-CL, a plurality of insulating patterns SP, a sensing insulating layer ISU-IL, and the first pad DP-PD. The base substrate SUB and the circuit element layer DP-CL illustrated in FIG. 9 may correspond to the base substrate SUB and the circuit element layer DP-CL of FIG. 6.

In an embodiment, the plurality of insulating patterns SP may be disposed on the base substrate SUB (e.g., in the third direction DR3). For example, in an embodiment the plurality of insulating patterns SP may be disposed on (e.g., disposed directly thereon in the third direction DR3) the fifth insulating layer 50 (see FIG. 6) of the circuit element layer DP-CL. In the present specification, the fifth insulating layer 50 may be referred to as an insulating layer 50. For example, the plurality of insulating patterns SP may be disposed between the base substrate SUB and the first pad DP-PD (e.g., in the third direction DR3). In an embodiment, the first pad DP-PD may cover the plurality of insulating patterns SP. The plurality of insulating patterns SP may overlap the bump BP in a plan view. In an embodiment, the plurality of insulating patterns SP may include a polymer material.

The plurality of insulating patterns SP may have a shape protruding in a thickness direction of the base substrate SUB (e.g., the third direction DR3). In an embodiment, the plurality of insulating patterns SP may be configured so that the first pad DP-PD may protrude towards a bump BP in a process of connecting the first pad DP-PD and the chip pad DC-PD to each other. FIG. 9 illustrates six insulating patterns SP each having a trapezoidal shape (e.g., in a cross-sectional view). However, embodiments of the present inventive concept are not necessarily limited thereto and a shape and the number of the insulating patterns SP may vary as long as the insulating patterns SP are formed so that the first pad DP-PD protrudes towards the bump BP. The plurality of insulating patterns SP may be disposed to be spaced apart from each other. For example, in an embodiment the plurality of insulating patterns SP may be disposed to be spaced apart in a direction parallel to the second direction DR2.

The sensing insulating layer ISU-IL may be disposed on the base substrate SUB (e.g., in the third direction DR3). For example, in an embodiment the sensing insulating layer ISU-IL may be disposed on the fifth insulating layer 50 of the circuit element layer DP-CL (e.g., disposed directly thereon in the third direction DR3). The sensing insulating layer ISU-IL may be formed to prevent electrical connection between the first pad DP-PD to be described later and another adjacent first pad DP-PD. In an embodiment, the sensing insulating layer ISU-IL may be formed through the same process as that for one of the first to third sensing insulating layers ISU-IL1, ISU-IL2, and ISU-IL3 (see FIG. 7) of the input sensor ISU (see FIG. 7). FIG. 9 illustrates the sensing insulating layer ISU-IL as one layer. However, embodiments of the present inventive concept are not necessarily limited thereto and the sensing insulating layer ISU-IL may include a plurality of layers. Sensing insulating layers ISU-IL may be disposed to be spaced apart from each other (e.g., in the second direction DR2). The plurality of insulating patterns SP may be disposed between sensing insulating layers ISU-IL adjacent to each other.

The first pad DP-PD may be disposed on the base substrate SUB (e.g., in the third direction DR3). For example, in an embodiment the first pad DP-PD may be disposed on (e.g., disposed directly thereon in the third direction DR3) the fifth insulating layer 50 (e.g., the insulating layer) of the circuit element layer DP-CL, and the first pad DP-PD may cover the plurality of insulating patterns SP.

In an embodiment, the driving chip DC may include the chip pad DC-PD, a bump electrode BP-CL, a metal layer BP-UM, and the bump BP.

The chip pad DC-PD may correspond to the first pad DP-PD. For example, in an embodiment the chip pad DC-PD may be disposed in one-to-one correspondence with the first pad DP-PD, and one chip pad DC-PD may be electrically connected to one first pad DP-PD through the bump BP.

The bump electrode BP-CL may partially cover the chip pad DC-PD. For example, in an embodiment the bump electrode BP-CL may cover an end of the chip pad DC-PD, and the chip pad DC-PD may be partially exposed by the bump electrode BP-CL. The bump electrode BP-CL may include a metal material. FIG. 9 illustrates one bump electrode BP-CL. However, embodiments of the present inventive concept are not necessarily limited thereto and a plurality of bump electrodes BP-CL may respectively partially cover a plurality of corresponding chip pads DC-PD. In this embodiment, the plurality of bump electrodes BP-CL may be spaced apart from each other through an insulating material (e.g., an insulating pattern or an insulating layer).

The metal layer BP-UM may be disposed on (e.g., disposed directly thereon) the chip pad DC-PD and the bump electrode BP-CL. In an embodiment, the metal layer BP-UM may be made of an easily adherable material so that the bump BP is easily formed on the chip pad DC-PD. For example, the metal layer BP-UM may include a metal material. In an embodiment, the metal layer BP-UM may include a plurality of metal layers and include a bonding layer, a diffusion prevention layer, or the like.

The metal layer BP-UM may include a plurality of metal patterns MPT. The bump BP to be described later may be formed on (e.g., disposed directly thereon) the metal layer BP-UM, and a plurality of first patterns PT1 and a plurality of second patterns PT2 may be formed in the bump BP by the plurality of metal patterns MPT which are formed in the metal layer BP-UM. For example, the plurality of first patterns PT1 of the bump BP may correspond to the plurality of metal patterns MPT. For example, the plurality of first patterns PT1 may correspond to a shape of the plurality of metal patterns MPT. The plurality of metal patterns MPT and the plurality of second patterns PT2 of the bump BP may overlap in a plan view. The plurality of metal patterns MPT may be in direct contact with a first surface S1 of the bump BP and a first recess GV1 of the plurality of first patterns PT1. For example, each of the plurality of metal patterns MPT may fill a first recess GV1 of the plurality of first patterns PT1. In an embodiment, the plurality of second patterns PT2 may correspond to the plurality of insulating patterns SP.

The bump BP may be disposed between the metal layer BP-UM and the first pad DP-PD (e.g., in the third direction DR3). The bump BP may overlap the plurality of insulating patterns SP in a plan view. The bump BP may electrically connect the first pad DP-PD of the display panel DP and the chip pad DC-PD of the driving chip DC to each other. The bump BP may be disposed on the metal layer BP-UM and be in direct contact with the first pad DP-PD, and thus transfer (e.g., directly transfer) an electric signal of the driving chip DC to the first pad DP-PD. The first surface S1 and a second surface S2 opposed to (e.g., opposite to) the first surface S1 may be defined (e.g., may be included) in the bump BP. The first surface S1 of the bump BP may be a surface adjacent to (e.g., directly adjacent thereto) the metal layer BP-UM and the second surface S2 of the bump BP may be a surface adjacent to (e.g., directly adjacent thereto) the first pad DP-PD. For example, the first pad DP-PD may be in direct contact with the second surface S2 of the bump BP.

The bump BP may include the plurality of patterns PT1 and PT2 which are formed on the first surface S1 and the second surface S2, respectively. In an embodiment, the plurality of patterns PT1 and PT2 of the bump BP may include the plurality of first patterns PT1 recessed from the first surface S1 in a thickness direction of the base substrate SUB (e.g., a direction opposite to the third direction DR3) and the plurality of second patterns PT2 recessed from the second surface S2 in a thickness direction of the base substrate SUB (e.g., the third direction DR3). For example, the plurality of first patterns PT1 may be adjacent to (e.g., directly adjacent to) the metal layer BP-UM, and the plurality of second patterns PT2 may be adjacent to (e.g., directly adjacent to) the first pad DP-PD.

The plurality of first patterns PT1 may include the first recess GV1 recessed from the first surface S1, and the plurality of second patterns PT2 may include a second recess GV2 recessed from the second surface S2. The first recess GV1 of the plurality of first patterns PT1 and the second recess GV2 of the plurality of second patterns PT2 may be alternately arranged along one direction, such as the second direction DR2. For example, in a cross-sectional view, the first recess GV1 and the second recess GV2 may be formed in a staggered manner. In an embodiment, the first recess GV1 may not overlap the second recess GV2 in a plan view. For example, in an embodiment, in a process of forming the bump BP, the plurality of first patterns PT1 are formed along (e.g., adjacent thereto in the second direction DR2) the plurality of metal patterns MPT of the metal layer BP-UM, and force is applied in a direction of gravity, and the second recess GV2 is formed between adjacent first recesses GV1. Detailed description thereof will be provided later.

In an embodiment, the plurality of first patterns PT1 and the plurality of second patterns PT2 may each include at least two recesses GV1 or GV2. The number of recesses of the plurality of first patterns PT1 and the number of recesses of the plurality of second patterns PT2 may correspond to the number of regions between the plurality of insulating patterns SP. FIG. 9 illustrates the plurality of second patterns PT2 having five second recesses GV2 of which the number corresponds to the number of the plurality of insulating patterns SP that is six, and the plurality of first patterns PT1 having four first recesses GV1 corresponding to the plurality of second patterns PT2. However, embodiments of the present inventive concept are not necessarily limited thereto, and the number of the recesses GV1 and GV2 of the plurality of first and second patterns PT1 and PT2 may vary.

The plurality of insulating patterns SP and the first pad DP-PD covering the plurality of insulating patterns SP may be designed within a scope of the limited dimensions of the display panel DP. To increase coupling reliability and coupling stability between the display panel DP and the driving chip DC, the plurality of second patterns PT2 may be configured to correspond to the number of the plurality of insulating patterns SP. The plurality of first patterns PT1 may be configured to correspond to the plurality of second patterns PT2.

In an embodiment, a step may be formed between an end and a center of a metal layer BP-UM. A bump BP may be formed on the metal layer BP-UM, and thus a shape of the metal layer BP-UM and a shape of the bump BP may correspond to each other, and a step may also be formed between an end and a center of the bump BP. During a process in which the bump BP and the first pad DP-PD are connected, due to the step of the bump BP, pressure may be concentrated on a plurality of insulating patterns SP overlapping the end of the bump BP, and sufficient pressure may not be provided to the center of the bump BP and a center of the first pad DP-PD. For example, when coupling the bump BP and the first pad DP-PD, pressure applied by the bump BP to the first pad DP-PD may not be uniform with respect to each of first pads DP-PD.

Since the bump BP of an embodiment of the present inventive concept may include the plurality of first and second patterns PT1 and PT2, the plurality of first and second patterns PT1 and PT2 may provide uniform pressure to a plurality of corresponding insulating patterns SP, and sufficient pressure may be provided to a center of the bump BP and a center of the first pad DP-PD. Thus, coupling reliability and coupling stability between the bump BP and the first pad DP-PD may be increased, and a decrease in contact resistance of the first pad DP-PD due to insufficient pressure at the center of the bump BP may be reduced or prevented.

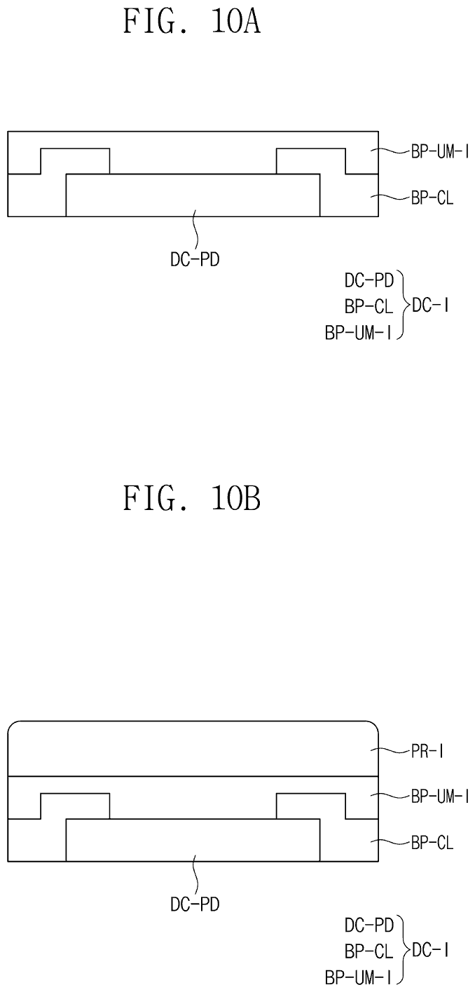

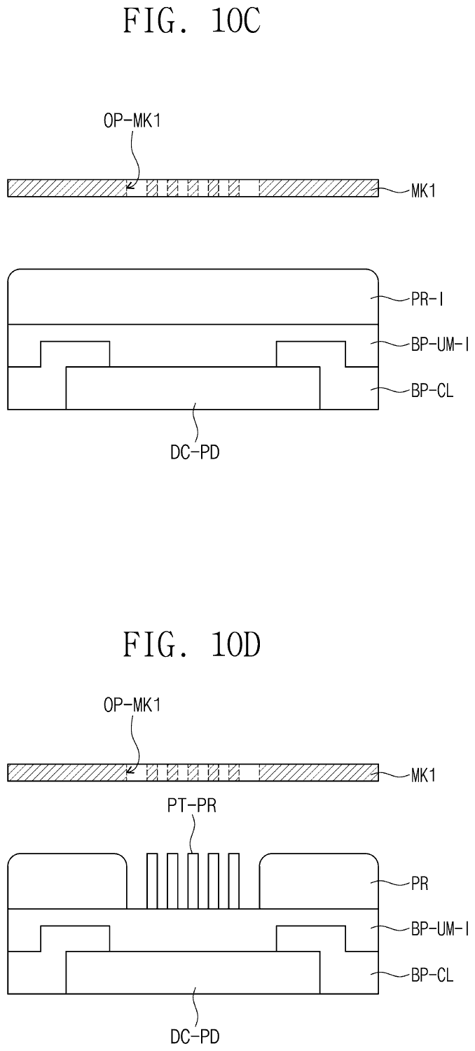

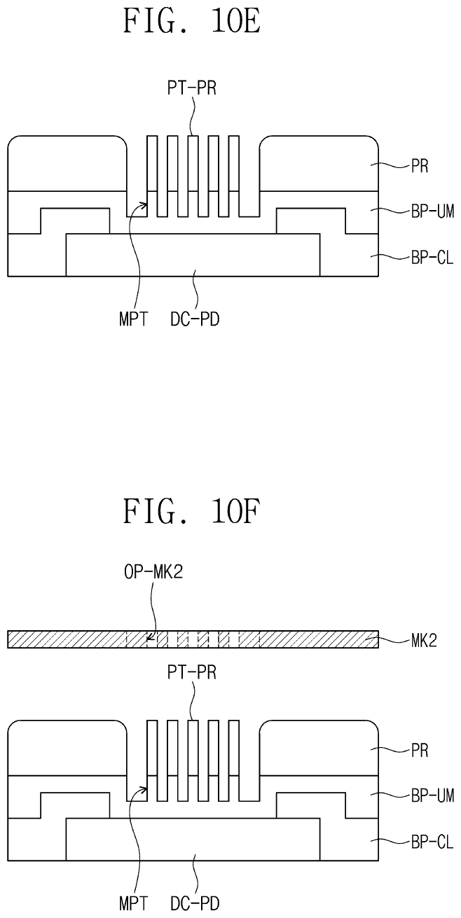

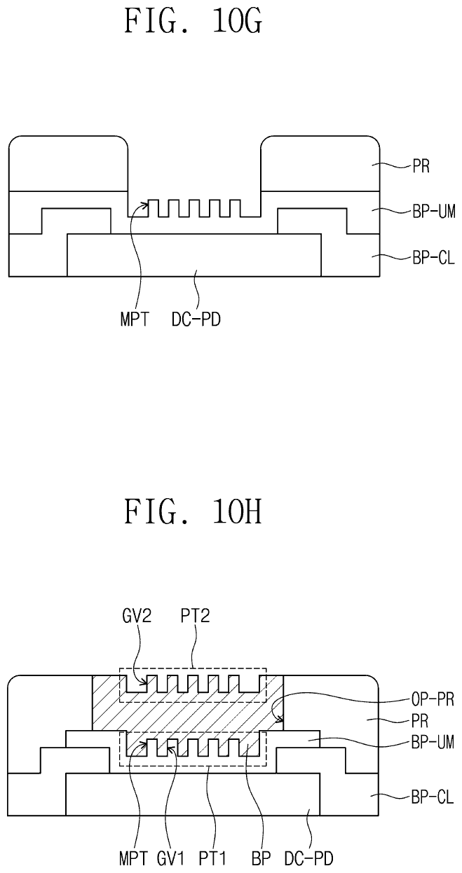

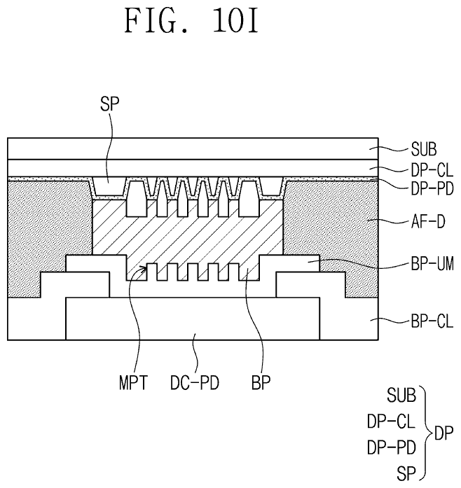

FIGS. 10A to 10I are cross-sectional views partially illustrating a manufacturing method for a display device according to embodiments of the present inventive concept. FIGS. 10A to 10I will be described with reference to FIGS. 1 to 9, and the same/a similar component will be denoted as the same/similar reference numerals or symbols. Descriptions overlapping with the above description may be omitted for economy of explanation. Hereinafter, a process in which a chip pad DC-PD of a driving chip DC and a first pad DP-PD of a display panel DP are coupled to each other will be described with reference to FIGS. 10A to 10I.

Referring to FIG. 10A, a manufacturing method for a display device of an embodiment of the present inventive concept may include preparing a preliminary driving chip DC-I. In an embodiment, the preliminary driving chip DC-I may include a chip pad DC-PD, a bump electrode BP-CL, and a preliminary metal layer BP-UM-I.

The bump electrode BP-CL may cover a portion of the chip pad DC-PD, and another portion of the chip pad DC-PD not covered with the bump electrode BP-CL may be exposed by the bump electrode BP-CL. The bump electrode BP-CL may include a metal material.

The preliminary metal layer BP-UM-I may be disposed on (e.g., disposed directly thereon) the chip pad DC-PD and the bump electrode BP-CL. In an embodiment, the preliminary metal layer BP-UM-I may be made of an easily adherable material so that a bump BP may be easily coupled onto the chip pad DC-PD. For example, the preliminary metal layer BP-UM-I may include a metal material.

Referring to FIGS. 10B to 10G, the manufacturing method for a display device of embodiments of the present inventive concept may include forming a metal layer BP-UM by etching the preliminary metal layer BP-UM-I.

First, referring to FIGS. 10B to 10D, in an embodiment the manufacturing method for a display device of the present inventive concept may include forming a photoresist layer PR (FIG. 10D) including a photo pattern PT-PR (FIG. 10D) on the preliminary driving chip DC-I.

Referring to FIG. 10B, the forming of the photoresist layer PR (see FIG. 10D) including the photo pattern PT-PR (see FIG. 10D) may include forming a preliminary photoresist layer PR-I on (e.g., directly thereon) the preliminary metal layer BP-UM-I. The preliminary photoresist layer PR-I may be formed to cover the preliminary metal layer BP-UM-I.

Referring to FIG. 10C, the forming of the photoresist layer PR (FIG. 10D) including the photo pattern PT-PR (FIG. 10D) may include aligning a first mask MK1 on the preliminary photoresist layer PR-I. A first mask opening OP-MK1 may be defined in the first mask MK1. The first mask opening OP-MK1 may overlap the portion of the chip pad DC-PD not covered with the bump electrode BP-CL.

Referring to FIG. 10D, the forming of the photoresist layer PR including the photo pattern PT-PR may include exposing the preliminary photoresist layer PR-I (see FIG. 10C) in a state in which the first mask MK1 is aligned. In an embodiment, the photo pattern PT-PR may be formed by exposing the preliminary photoresist layer PR-I using the first mask MK1. For example, a portion of the preliminary photoresist layer PR-I exposed to light in an exposure process may be removed, and the photo pattern PT-PR may be formed from a portion of the preliminary photoresist layer PR-I not exposed to light. The photo pattern PT-PR not overlapping the first mask opening OP-MK1 may be formed in the photoresist layer PR through a patterning process.

FIG. 10D illustrates and describes a positive PR method. However, embodiments of the present inventive concept are not necessarily limited thereto and the photoresist layer PR may be patterned using a negative PR method in some embodiments.

Referring to FIGS. 10E to 10G, the manufacturing method for a display device of embodiments of the present inventive concept may include forming a plurality of metal patterns MPT corresponding to the photo pattern PT-PR.

First, referring to FIG. 10E, the forming of the plurality of metal patterns MPT of an embodiment of the present inventive concept may include partially etching the preliminary metal layer BP-UM-I (see FIG. 10D) using the photo pattern PT-PR. In an embodiment, the etching of the preliminary metal layer BP-UM-I may be performed through dry etching. A portion of the preliminary metal layer BP-UM-I not overlapping the photo pattern PT-PR may be etched and removed, and the plurality of metal patterns MPT may be formed from a portion of the preliminary metal layer BP-UM-I overlapping the photo pattern PT-PR.

Referring to FIGS. 10F and 10G, the forming of the plurality of metal patterns MPT of embodiments of the present inventive concept may include removing the photo pattern PT-PR. In an embodiment, the removing of the photo pattern PT-PR may include disposing a second mask MK2 and removing the photo pattern PT-PR using the second mask MK2.

The second mask MK2 may be aligned on the photoresist layer PR. A second mask opening OP-MK2 may be defined in the second mask MK2. The second mask opening OP-MK2 may overlap the photo pattern PT-PR. In the removing of the photo pattern PT-PR, the photo pattern PT-PR may be exposed using the second mask MK2. The photo pattern PT-PR exposed to light passing through the second mask opening OP-MK2 may be removed. During a process of removing the photo pattern PT-PR, the metal layer BP-UM may also be partially removed. For example, the plurality of metal patterns MPT of the metal layer BP-UM may be partially removed, such as in a vertical direction.

Then, referring to FIG. 10H, the manufacturing method for a display device of an embodiment of the present inventive concept may include forming the bump BP on (e.g., directly thereon) the metal layer BP-UM. The bump BP may be formed along the plurality of metal patterns MPT which are formed in the metal layer BP-UM. The bump BP may include a plurality of first patterns PT1 and a plurality of second patterns PT2. In an embodiment, the forming of the bump BP on the metal layer BP-UM may include forming the plurality of first patterns PT1 corresponding to a shape of the plurality of metal patterns MPT and forming the plurality of second patterns PT2 corresponding to the plurality of first patterns PT1.

In an embodiment, the bump BP may be formed in an opening OP-PR defined by the photoresist layer PR. The bump BP may be formed on the metal layer BP-UM, and the plurality of first patterns PT1 engaging with the plurality of metal patterns MPT may be formed. The plurality of first patterns PT1 may be adjacent to (e.g., directly adjacent to) the metal layer BP-UM. In an embodiment, the plurality of first patterns PT1 may include a first recess GV1 recessed from the first surface S1 (see FIG. 9) of the bump BP in a thickness direction of the base substrate SUB (see FIG. 9).

In an embodiment, the plurality of second patterns PT2 may be formed to correspond to a shape of the plurality of first patterns PT1. The plurality of second patterns PT2 may include a second recess GV2 recessed from the second surface S2 (see FIG. 9) of the bump BP in a thickness direction of the base substrate SUB. The first recess GV1 of the plurality of first patterns PT1 and the second recess GV2 of the plurality of second patterns PT2 may be alternately arranged along one direction, such as a second direction DR2. For example, in a cross-sectional view, the first recess GV1 and the second recess GV2 may be formed in a staggered manner (e.g., along the second direction DR2). The first recess GV1 may not overlap the second recess GV2 in a plan view.

This arrangement may be formed in a process of forming the bump BP when the plurality of first patterns PT1 are formed along (e.g., adjacent thereto in the second direction DR2) the plurality of metal patterns MPT of the metal layer BP-UM, due to force being applied in a direction of gravity, and the second recess GV2 is formed between adjacent first recesses GV1. For example, this is because the plurality of second patterns PT2 are formed to correspond to the plurality of first patterns PT1. The plurality of second patterns PT2 may be formed to be spaced apart from the metal layer BP-UM in a cross-sectional view. The plurality of second patterns PT2 may be a portion coupled to a display panel DP to be described later.

Referring to FIG. 10I, the manufacturing method for a display device of the present inventive concept may include, after removing the photoresist layer PR, preparing the display panel DP and electrically connecting the chip pad DC-PD and a first pad DP-PD to each other.

In an embodiment, the display panel DP may include a base substrate SUB, a circuit element layer DP-CL disposed on the base substrate SUB, a plurality of insulating patterns SP disposed on the circuit element layer DP-CL, and the first pad DP-PD covering the plurality of insulating patterns SP.

The chip pad DC-PD and the first pad DP-PD may be electrically connected to each other through the bump BP. For example, a driving chip adhesive member AF-D surrounding the bump BP may couple a driving chip DC and the display panel DP to each other. As a result, the chip pad DC-PD of the driving chip DC may be electrically connected to the first pad DP-PD of the display panel DP.

The plurality of metal patterns MPT may be formed in the metal layer BP-UM through a process of etching the preliminary metal layer BP-UM-I. Since the bump BP may be formed on the metal layer BP-UM, the plurality of first patterns PT1 engaging with the plurality of metal patterns MPT and the plurality of second patterns PT2 corresponding to the plurality of first patterns PT1 may be formed in the bump BP. The plurality of first and second patterns PT1 and PT2 of the bump BP may provide uniform pressure to a plurality of corresponding insulating patterns SP, and sufficient pressure may be provided to a center of the bump BP and a center of the first pad DP-PD. For example, the bump BP and the first pad DP-PD may be connected with uniform pressure, equal to the pressure at an end of the first pad DP-PD, not only at an end of the bump BP but also at the center of the bump BP. As a result, a concentration of pressure on the end of the bump BP during a process of connecting the bump BP and the first pad DP-PD may be reduced or prevented, and coupling reliability and coupling stability between the bump BP and the first pad DP-PD may be increased. Thus, a decrease in contact resistance of the first pad DP-PD due to insufficient pressure at the center of the bump BP may be reduced or prevented.

According to the description above, since a bump of the present inventive concept may include a plurality of first and second patterns, the plurality of first and second patterns may provide uniform pressure to a plurality of corresponding insulating patterns, and sufficient pressure may be provided to a center of the bump and a center of a first pad. Thus, coupling reliability (or, coupling stability) between the bump and the first pad may be improved, and a decrease in contact resistance of the first pad due to insufficient pressure at the center of the bump may be reduced or prevented.

Although the embodiments of the present inventive concept have been described, it is understood that the present inventive concept should not be limited to these described embodiments, but various changes and modifications may be made by one of ordinary skilled in the art within the spirit and scope of the present inventive concept as hereinafter claimed. Therefore, the technical scope of the present inventive concept is not limited to the embodiments described in the detailed description of the specification.

What is claimed is:

1. A display device comprising:
a display panel including a base substrate and a first pad disposed on the base substrate;
a driving chip including a chip pad corresponding to the first pad and a bump electrically connecting the first pad and the chip pad to each other; and
an adhesive member disposed between the display panel and the driving chip, the adhesive member coupling the first pad and the chip pad to each other, and the adhesive member contacted with side of the bump
wherein the bump includes a first surface and a second surface opposite to the first surface in a thickness direction of the base substrate, and the bump includes a plurality of patterns on the first surface and the second surface.

2. The display device of claim 1, wherein the first pad is in direct contact with the second surface of the bump.

3. The display device of claim 1, wherein:
the display panel further comprises a plurality of insulating patterns disposed between the base substrate and the first pad; and
the first pad covers the plurality of insulating patterns.

4. The display device of claim 3, wherein the plurality of insulating patterns overlaps the bump in a plan view.

5. The display device of claim 1, wherein the driving chip comprises a bump electrode partially covering the chip pad and a metal layer disposed on the chip pad and the bump electrode.

6. The display device of claim 5, wherein the bump is disposed between the metal layer and the first pad in the thickness direction of the base substrate.

7. The display device of claim 5, wherein the plurality of patterns of the bump comprises:
a plurality of first patterns recessed from the first surface in the thickness direction of the base substrate; and
a plurality of second patterns recessed from the second surface in the thickness direction of the base substrate.

8. The display device of claim 7, wherein:
the plurality of first patterns comprise a first recess recessed from the first surface in the thickness direction of the base substrate;
the plurality of second patterns comprise a second recess recessed from the second surface in the thickness direction of the base substrate; and
the first recess of the plurality of first patterns and the second recess of the plurality of second patterns are alternately arranged along one direction.

9. The display device of claim 8, wherein the metal layer comprises a plurality of metal patterns corresponding to the plurality of first patterns of the bump.

10. The display device of claim 9, wherein the plurality of second patterns overlaps the plurality of metal patterns of the metal layer.

11. The display device of claim 9, wherein the plurality of metal patterns of the metal layer is in direct contact with the first surface of the bump and the first recess of the plurality of first patterns.

12. The display device of claim 7, wherein:
the plurality of first patterns comprise a first recess recessed from the first surface;
the plurality of second patterns comprise a second recess recessed from the second surface; and
the first recess does not overlap the second recess in a plan view.

13. The display device of claim 7, wherein:
the plurality of first patterns is adjacent to the metal layer; and
the plurality of second patterns are adjacent to the first pad.

14. The display device of claim 7, wherein the plurality of first patterns and the plurality of second patterns each comprise a plurality of recesses.

15. A manufacturing method for a display device, the manufacturing method comprising:
preparing a preliminary driving chip including a chip pad, a bump electrode partially covering the chip pad, and a preliminary metal layer disposed on the chip pad and the bump electrode;
etching the preliminary metal layer to form a metal layer; and
forming a bump on the metal layer, the bump including a plurality of first patterns and a plurality of second patterns,
wherein the plurality of first patterns is adjacent to the metal layer, and the plurality of second patterns are spaced apart from the metal layer in a cross-sectional view.

16. The manufacturing method of claim 15, further comprising forming a photoresist layer on the preliminary driving chip, the photoresist layer including a photo pattern,
wherein the forming of the metal layer by etching the preliminary metal layer includes forming a plurality of metal patterns corresponding to the photo pattern.

17. The manufacturing method of claim 15, further comprising:
preparing a display panel including a base substrate, a plurality of insulating patterns disposed on the base substrate, and a first pad covering the plurality of insulating patterns; and
electrically connecting the chip pad and the first pad to each other by the bump.

18. The manufacturing method of claim 16, wherein the forming of the bump on the metal layer comprises:
forming the plurality of first patterns corresponding to a shape of the plurality of metal patterns; and
forming the plurality of second patterns corresponding to the plurality of first patterns.

19. An electronic device for provide an image, comprising:
a display device comprising
a display panel including a base substrate and a first pad disposed on the base substrate;
a driving chip including a chip pad corresponding to the first pad and a bump electrically connecting the first pad and the chip pad to each other; and
an adhesive member disposed between the display panel and the driving chip, the adhesive member coupling the first pad and the chip pad to each other,
wherein the bump includes a first surface and a second surface opposite to the first surface in a thickness direction of the base substrate, and the bump includes a plurality of patterns on the first surface and the second surface.

20. The electronic device of claim 19, wherein the driving chip further comprises a bump electrode partially covering the chip pad and a metal layer disposed on the chip pad and the bump electrode,
the bump comprises:
a plurality of first patterns recessed from a first surface adjacent to the metal layer in a thickness direction of the base substrate; and
a plurality of second patterns recessed from a second surface adjacent to the first pad in the thickness direction of the base substrate,
wherein the plurality of second patterns correspond to the plurality of insulating patterns.
